(19) United States
(12) Patent Application Publication
(10) Pub. No.: US 2013/0014797 A1
(43) Pub. Date: Jan. 17, 2013

(54) SUPPLYING ELECTRICAL POWER IN A HYDROCARBON WELL INSTALLATION

(71) Applicant: Nicholas ELLSON, Bristol (GB)

(72) Inventor: Nicholas ELLSON, Bristol (GB)

(21) Appl. No.: 13/418,792

(22) Filed: Mar. 13, 2012

(30) Foreign Application Priority Data
Mar. 17, 2011 (EP) 11158605.3

(51) Int. Cl. H01L 35/32; B23P 11/00

(52) U.S. Cl. 136/205; 29/428

(57) ABSTRACT

A method of providing electrical power in an underwater hydrocarbon well installation comprising a pipeline for conveying a hydrocarbon fluid is provided. The method comprises attaching at least one clamp to the pipeline at the outside of the pipeline, the clamp housing at least one thermoelectric generating device so that the device is in a temperature gradient resulting from a difference in temperature between the hydrocarbon fluid and the water surrounding the pipeline.

### BACKGROUND OF THE INVENTION

1. Field of the Invention

Embodiments of the invention relate generally to supplying electrical power in an underwater hydrocarbon well installation.

2. Description of Related Art

In offshore oil production control systems, much of the control equipment is installed on the seabed. This subsea equipment, which essentially opens and closes subsea valves that control and allow the flow of fluid from the well, has to be highly reliable and operate in the harsh environment subsurface and is required to operate satisfactory over a life of up to 25 years. Electrical power for this equipment installed on the seabed is provided by an electrical power unit installed topside, either on a rig, floating platform or onshore for example.

The electrical power is carried to the subsea equipment via an umbilical cable, which also includes a communication link (that carries control and instrumentation signals) together with hydraulic pipelines which carry the hydraulic fluid for electrically actuated hydraulic fluid control valves. The umbilical cable may be several kilometres long, is heavy and expensive. The design of an umbilical cable is therefore critical and should be as cost-effective as possible. The configuration adopted may limit the availability of additional electrical power should modifications be required to the subsea equipment at a later date.

So-called “brown-field” developments can require more electrical power and sensing and measurements than the original umbilical cable and infield infrastructure were designed for. A method of providing small amounts of additional electrical power at a later date, without the need to modify, an umbilical cable is highly desirable. Examples of this are when additional sensors are required at the subsea installation which requires electrical power or when power is needed to operate an additional acoustic communication system (for example based on hydrophones).

### BRIEF SUMMARY OF THE INVENTION

According to an embodiment of the present invention, a method of providing electrical power in an underwater hydrocarbon well installation comprising a pipeline for conveying a hydrocarbon fluid is provided. The method comprises attaching at least one clamp to the pipeline at the outside of the pipeline, the clamp housing at least one thermoelectric generating device so that the device is in a temperature gradient resulting from a difference in temperature between the hydrocarbon fluid and the water surrounding the pipeline.

According to another embodiment of the present invention, an apparatus for providing electrical power in an underwater hydrocarbon well installation comprising a pipeline for conveying a hydrocarbon fluid is provided. The apparatus comprises at least one clamp configured to be attached to the outside of the pipeline, wherein the clamp houses at least one thermoelectric generating device so that the device is in a temperature gradient resulting from a difference in temperature between the hydrocarbon fluid and water surrounding the pipeline.

### BRIEF DESCRIPTION OF THE SEVERAL VIEWS OF THE DRAWINGS

Other features and advantages of embodiments of the invention will become further apparent from the description which follows, which is purely illustrative and should be read with reference to the accompanying drawings, in which:

FIG. 1 is a transverse section through a pipeline having a thermoelectric power generation device attached to it according to an embodiment of the invention; and

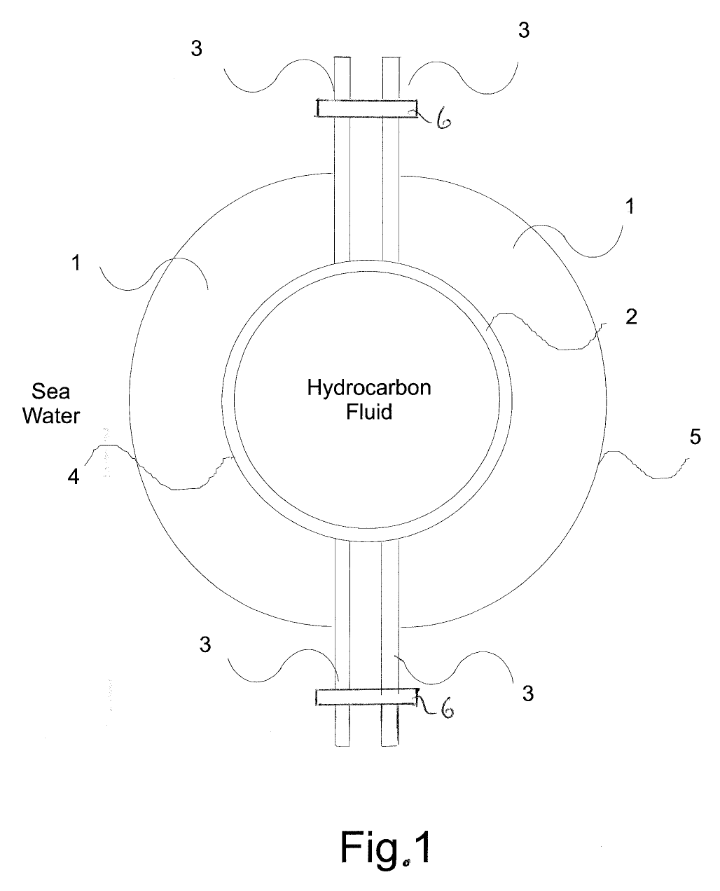

FIG. 2 is a longitudinal section of the embodiment shown in FIG. 1.

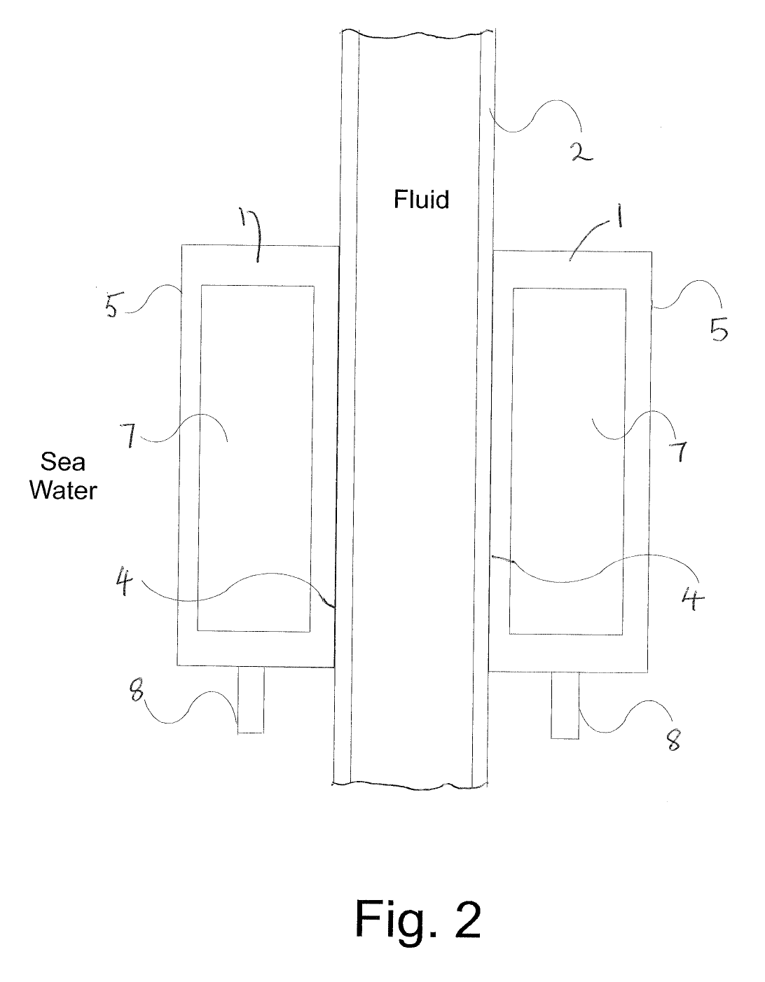

### DETAILED DESCRIPTION OF THE INVENTION

Embodiments of the present invention utilize the integration of thermoelectric electrical power generating devices in the form of modules into a clamp arrangement applied around a pipeline transporting hot hydrocarbon fluid emerging from an offshore oil well and which is suitable for operating in the harsh environment at the seabed. In this configuration, there is an overall temperature difference between the temperature of the hot fluid and the temperature of sea water surrounding the pipeline and this is adequate to provide a temperature gradient across the thermoelectric modules to enable sufficient power to be generated to operate, for example, small sensors.

Embodiments of the present invention utilize the proven characteristics of solid state semiconductor based thermoelectric electrical power generating modules when subjected to a temperature gradient across them, to generate sufficient electrical power to operate small instrumentation. Although power output and generation efficiency are very low, useful power can be obtained given the temperature gradient available.

An embodiment of the invention utilizes the temperature difference between hot hydrocarbon fluid emerging up a subsea pipeline from an offshore oil well (which is typically at about 70 degrees C.) and the subsea temperature outside the pipeline wall (which is typically about 5 degrees C.). Calculations show that this temperature gradient can be sufficient to generate more than 3 watts of DC electrical power when utilizing currently available thermoelectric modules mounted in a clamp arrangement surrounding the pipeline.

Referring to the figures, thermoelectric generation is provided by integrating sufficient solid state semiconductor based thermoelectric modules in a clamp arrangement which comprises two substantially semi-circular, C-shaped bodies 1 each forming a clamp half, which are assembled and clamped around a fluid flow pipeline 2 carrying hot hydrocarbon fluid. Each C-shaped body 1 carries a flange 3 at each end, each of which is fastened to an opposite flange 3 of the other body 1 by suitable fastening means 6. The inner surfaces 4 of the casings of the bodies 1, when installed, are in contact with the external surface of the hot hydrocarbon fluid carrying pipeline 2, while the outer surfaces 5 of the casings of the bodies 1 are in contact with the relatively cold sea water. The thermoelectric modules 7 are housed within the bodies 1, there being a temperature gradient across the thermoelectric modules.

The clamp is positioned around the pipeline 2 with the inner surfaces 4 of the casings of the bodies 1 arrangement in contact with the fluid pipeline while their external surfaces 5 are in contact with the sea water, the semiconductor based thermoelectric power generation modules 7 being housed inside the casings of the bodies 1. Electrical connections 8 are brought out to a subsea connector at the base of the arrangement (which may be permanently or temporarily connected to the load(s) using dry or wet male connectors). The length of the surfaces 4 in contact with the fluid pipeline 2 will depend on the output power required by the load(s), such as sensor(s) and/or other instrumentation.

Typically, the clamp arrangement is deployable or retrievable subsea by a remotely operated vehicle (ROV).

Suitable thermoelectric modules are available on the market in several physical sizes (such as 0.5 inch×0.5 inch, 1 inch×1 inch) which are suitable for packaging in a corrosion proof clamp arrangement. Use can be made of the relatively high mechanical strength in a compression mode (shear strength is comparatively low). When modules are installed using the above clamping method, sufficient pressure will have to be maintained on them so that a module is not “loose” so that it may easily be moved by applying a small lateral force.

Thermoelectric modules are highly reliable components due to their solid state construction and provide long, trouble-free service.

Embodiments of the present invention provide for solid state power generation with no moving parts. Embodiments also provide DC power generation with no need for power conversion. Embodiments also employ low power, low cost thermoelectric modules used in a variety of applications. Furthermore, embodiments of the present invention provide a clamp-on installation that simplifies retrofitting. Additionally, embodiments of the present invention enable more sensors and measurements to be added to a brown-field facility and also reduces infrastructure required on a green-field installation.

What is claimed is:

1. A method of providing electrical power in an underwater hydrocarbon well installation comprising a pipeline for conveying a hydrocarbon fluid, the method comprising attaching at least one clamp to the pipeline at the outside of the pipeline, the clamp housing at least one thermoelectric generating device so that the device is in a temperature gradient resulting from a difference in temperature between the hydrocarbon fluid and the water surrounding the pipeline.

2. The method of claim 1, wherein the clamp is C-shaped.

3. The method of claim 2, further comprising attaching a second C-shaped clamp to the outside of the pipeline opposite the first C-shaped clamp, wherein the second C-shaped clamp houses at least one thermoelectric generating device.

4. The method of claim 3, wherein each of the first and second C-shaped clamps comprise a flange at each end, and wherein attaching at least one body to the pipeline comprises fastening each flange to a flange of the opposite clamp.

5. The method of claim 1, wherein the at least one clamp is attached to the pipeline using an ROV.

6. The method of claim 1, wherein the clamp is C-shaped and wherein the method further comprises attaching a second C-shaped clamp to the outside of the pipeline opposite the first C-shaped clamp, wherein the second C-shaped clamp houses at least one thermoelectric generating device, and wherein each thermoelectric generating device is housed in the respective clamp.

7. The method of claim 6, wherein each of the first and second C-shaped clamps comprise a flange at each end, and wherein attaching at least one clamp to the pipeline comprises fastening each flange to a flange of the opposite clamp.

8. The method of claim 6 wherein the at least one body is attached to the pipeline using an ROV.

9. An apparatus for providing electrical power in an underwater hydrocarbon well installation comprising a pipeline for conveying a hydrocarbon fluid, the apparatus comprising at least one clamp configured to be attached to the outside of the pipeline, wherein the clamp houses at least one thermoelectric generating device so that the device is in a temperature gradient resulting from a difference in temperature between the hydrocarbon fluid and water surrounding the pipeline.

10. The apparatus of claim 9, wherein the clamp is C-shaped.

11. The apparatus of claim 10, further comprising a second C-shaped clamp configured to be attached to the outside of the pipeline opposite the first clamp, wherein the second C-shaped clamp houses at least one thermoelectric generating device.

12. The apparatus of claim 11, wherein each of the first and second C-shaped clamps comprise a flange at each end, wherein each flange is configured to be fastened to a flange of the opposite body.
